(19) United States
(12) Patent Application Publication
(10) Pub. No.: US 2026/0311975 A1
(43) Pub. Date: Oct. 8, 2026

(54) WAFER PLACEMENT TABLE

(71) Applicant: NGK Corporation, Nagoya-shi (JP)

(72) Inventors: Tatsuya KUNO, Nagoya-city (JP); Seiya INOUE, Handa-city (JP)

(21) Appl. No.: 19/681,764

(22) Filed: May 19, 2026

Related U.S. Application Data
(63) Continuation of application No. PCT/JP2024/014961, filed on Apr. 15, 2024.

(51) Int. Cl. H01J 37/32

(52) U.S. Cl. CPC H01J 37/32715; H01J 37/3244; H01J 37/32541; H01J 37/32568; H01J 37/32697; H01J 2237/0206

(57) ABSTRACT

A wafer placement table includes: a ceramic plate having a wafer placement surface on its upper surface; a gas passage through which gas can pass in an up-down direction of the ceramic plate; a conductive base plate bonded to a lower surface of the ceramic plate and used as a plasma generation electrode; and a gas supply path provided inside the base plate and communicating with the gas passage. The wafer placement table further includes an electric-field-adjusting conductor. The electric-field-adjusting conductor is provided so as to extend in an up-down direction in the vicinity of the gas passage from a position at the lower surface of the ceramic plate or a position below the lower surface to a position short of the wafer placement surface, and is electrically connected to the base plate.

### CROSS-REFERENCE TO RELATED APPLICATION

This application is a continuation application of PCT/JP2024/014961, filed on Apr.15, 2024, is incorporated herein by reference in its entirety.

### BACKGROUND OF THE INVENTION

### 1. Field of the Invention

The present invention relates to a wafer placement table.

### 2. Description of the Related Art

Conventionally, a wafer placement table is used in a semiconductor manufacturing apparatus. For example, the wafer placement table of PTL 1 includes a ceramic plate having a wafer placement surface on its upper surface, a gas passage through which gas can pass in an up-down direction of the ceramic plate, a conductive base plate bonded to a lower surface of the ceramic plate, and a gas supply path provided inside the base plate. The gas passage is constituted by a porous plug disposed in a through hole formed in the ceramic plate. In such a wafer placement table, a high-frequency voltage is applied between the base plate and an upper electrode disposed above the wafer to generate plasma above the wafer, and the wafer is processed by the plasma. At this time, helium gas is introduced into the gas supply path from outside. The helium gas is then supplied to the lower surface side of the wafer through the gas supply path and the gas passage, thereby improving thermal conduction between the wafer and the ceramic plate. Since the helium gas passes through pores of the porous plug, it is possible to suppress occurrence of arc discharge on the lower surface side of the wafer as compared with a case where the porous plug is absent. Without the porous plug, arc discharge occurs when electrons generated in association with ionization of helium are accelerated and collide with other helium; however, with the porous plug, the electrons hit the porous plug before colliding with other helium, thereby suppressing arc discharge. If arc discharge occurs on the lower surface side of the wafer, the wafer is deteriorated and cannot be used as a device, which is undesirable.

### Citation List

### Patent LIterture

PTL 1: JP2019-29384 A

### SUMMARY OF THE INVENTION

However, in such a wafer placement table, development of a new structure for suppressing discharge within the gas passage has been desired.

The present invention has been made to solve the above-described problem, and a primary object thereof is to provide a new structure for suppressing discharge within the gas passage.

[1] A wafer placement table of the present invention includes: a ceramic plate having a wafer placement surface on its upper surface; a gas passage through which gas can pass in an up-down direction of the ceramic plate; a conductive base plate bonded to a lower surface of the ceramic plate and used as a plasma generation electrode; a gas supply path provided inside the base plate and communicating with the gas passage; and an electric-field-adjusting conductor provided so as to extend in an up-down direction in the vicinity of the gas passage from a position at a lower surface of the ceramic plate or a position below the lower surface to a position short of the wafer placement surface, the electric-field-adjusting conductor being electrically connected to the base plate.

In this wafer placement table, by providing the electric-field-adjusting conductor, a direction of an electric field at the time of plasma generation (a direction orthogonal to equipotential lines) can be adjusted to a horizontal direction or a direction close thereto. Accordingly, a direction in which electrons generated in association with ionization of gas molecules are accelerated becomes a horizontal direction or a direction close thereto. Therefore, if a length of the gas passage in the horizontal direction or a direction close thereto is short, even when an up-down-direction length in the gas passage is increased, a distance over which electrons are accelerated does not become long, and discharge is less likely to occur even if accelerated electrons collide with other gas molecules. Thus, as compared with a case where the electric-field-adjusting conductor is not provided, discharge within the gas passage can be suppressed even when the up-down-direction length in the gas passage is increased.

In the present specification, the invention may be described using terms such as up-down, left-right, and front-back; however, these directions are merely relative positional relationships. Therefore, when an orientation of the wafer placement table is changed, up-down may become left-right or left-right may become up-down; such cases are also included in the technical scope of the present invention.

[2] In the wafer placement table (the wafer placement table described in [1] above), the ceramic plate may have at least one electrode, the gas passage may be provided so as to pass through an electrode through hole provided for each of the at least one electrode such that each of the at least one electrode is not exposed on an inner surface of the gas passage, and the electric-field-adjusting conductor may be provided in a state electrically insulated from each of the at least one electrode. This makes it possible to make a direction of an electric field generated by the electrode(s) in the ceramic plate also a horizontal direction or a direction close thereto.

[3] In the wafer placement table (the wafer placement table described in [1] or [2] above), the ceramic plate may have a ceramic-plate through hole penetrating the ceramic plate in the up-down direction, the gas passage may be provided in an interior of a plug disposed in the ceramic-plate through hole or around the plug, and the electric-field-adjusting conductor may be provided in an interior of the plug. This may facilitate forming the gas passage and the electric-field-adjusting conductor as compared with a case where the gas passage and the electric-field-adjusting conductor are provided directly in the ceramic plate itself.

[4] In the wafer placement table (the wafer placement table described in [1] or [2] above), the gas passage and the electric-field-adjusting conductor may be provided in the ceramic plate. This makes it possible to build the gas passage and the electric-field-adjusting conductor into the ceramic plate when manufacturing the ceramic plate.

[5] In the wafer placement table (the wafer placement table described in any one of [1] to [4] above), the gas passage may be provided linearly in the up-down direction or an oblique direction. This allows an increased gas flow rate since gas flows more easily as compared with a case where a spiral passage is employed as the gas passage or where fine pores inside a porous body are used as the gas passage.

[6] In the wafer placement table (the wafer placement table described in any one of [1] to [5] above), the electric-field-adjusting conductor may be a flexible conductive wire. The electric-field-adjusting conductor may be a highly rigid needle-like member; however, in view of positional deviation during manufacturing and deformation during use, it is preferable that the electric-field-adjusting conductor is a flexible conductive wire.

[7] In the wafer placement table (the wafer placement table described in any one of [1] to [6] above), a lower portion of the electric-field-adjusting conductor may be provided so as to directly contact the base plate, or may be electrically connected to the base plate by a conductive elastic body that is disposed between the base plate and a lower end of the electric-field-adjusting conductor and that maintains a communicating state between the gas supply path and the gas passage, or may be electrically connected to the base plate via a conductive film that is provided on a lower surface of the ceramic plate and that maintains the communicating state between the gas supply path and the gas passage.

### BRIEF DESCRIPTION OF THE DRAWINGS

FIG. 1 is a plan view of a wafer placement table 10.

FIG. 2 is a cross-sectional view taken along line A-A of FIG. 1.

FIG. 3 is a partially enlarged view of FIG. 2.

FIG. 4 is a partially enlarged cross-sectional view of a comparative embodiment.

FIGS. 5A to 5C are manufacturing process diagrams of the wafer placement table 10.

FIG. 6 is a partially enlarged cross-sectional view of another embodiment.

FIG. 7 is a partially enlarged cross-sectional view of another embodiment.

FIG. 8 is a partially enlarged cross-sectional view of another embodiment.

FIG. 9 is a partially enlarged cross-sectional view of another embodiment.

FIG. 10 is a partially enlarged cross-sectional view of another embodiment.

FIG. 11 is a partially enlarged cross-sectional view of another embodiment.

FIG. 12 is a partially enlarged cross-sectional view of another embodiment.

### DETAILED DESCRIPTION OF THE INVENTION

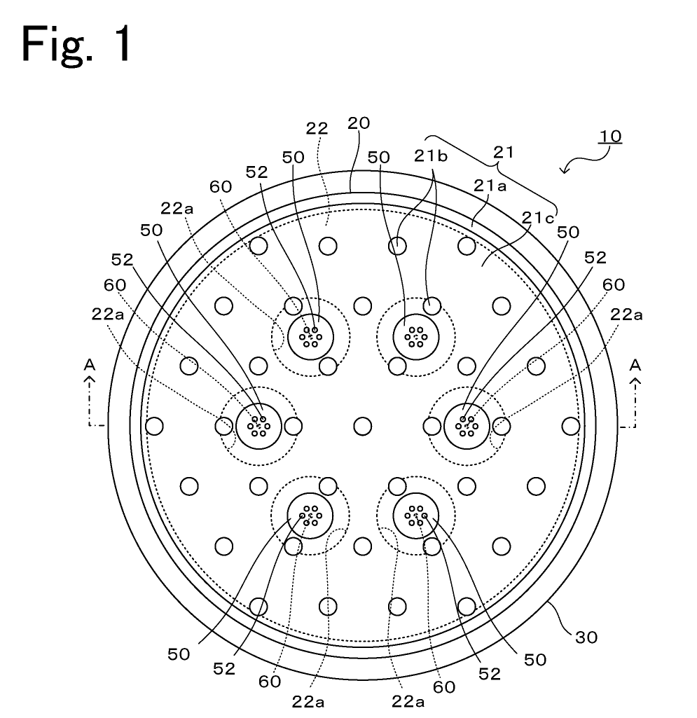

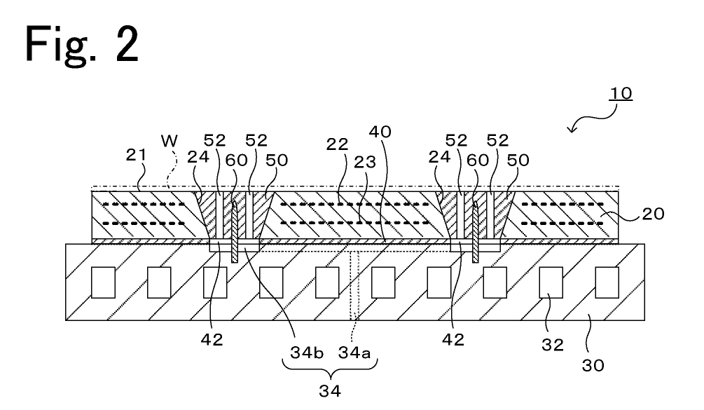

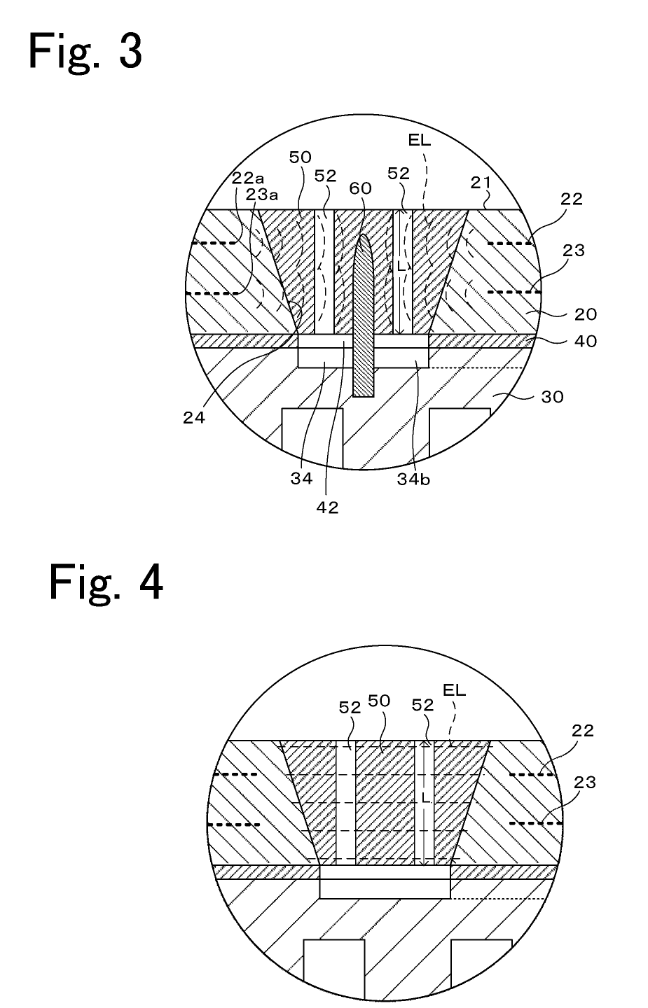

Preferred embodiments of the present invention will be described with reference to the drawings. FIG. 1 is a plan view of a wafer placement table 10, FIG. 2 is a cross-sectional view taken along line A-A of FIG. 1, and FIG. 3 is a partially enlarged view of FIG. 2. In FIG. 2 and FIG. 3, for convenience, a seal band 21a, circular small projections 21b, and a reference surface 21c of the wafer placement surface 21 are omitted.

The wafer placement table 10 includes a ceramic plate 20, gas passages 52, a base plate 30, a metal bonding layer 40, and an electric-field-adjusting conductor 60.

The ceramic plate 20 is a ceramic disk (for example, having a diameter of 300 mm and a thickness of 5 mm) made of ceramic such as a sintered alumina body or a sintered aluminum nitride body. An upper surface of the ceramic plate 20 is a wafer placement surface 21. The ceramic plate 20 incorporates an electrostatic electrode 22 and a bias electrode 23. The electrostatic electrode 22 is provided at a position near the wafer placement surface 21 (for example, a position 0.05 to 0.2 mm from the wafer placement surface 21), and the bias electrode 23 is provided at a position farther from the wafer placement surface 21. As shown in FIG. 1, a seal band 21a is formed along an outer edge on the wafer placement surface 21 of the ceramic plate 20, and a plurality of circular small projections 21b are formed over the entire surface. The seal band 21a and the circular small projections 21b have the same height, and the height is, for example, several μm to several tens of μm. The electrostatic electrode 22 is, for example, a planar mesh electrode and is configured such that a DC voltage can be applied thereto. When a DC voltage is applied to the electrostatic electrode 22, the wafer W is attracted and fixed to the wafer placement surface 21 (specifically, an upper surface of the seal band 21a and upper surfaces of the circular small projections 21b) by an electrostatic attractive force, and when application of the DC voltage is stopped, the attraction and fixing of the wafer W to the wafer placement surface 21 is released. A portion of the wafer placement surface 21 where the seal band 21a and the circular small projections 21b are not provided is referred to as a reference surface 21c. The bias electrode 23 is, for example, a planar mesh electrode, and a bias high frequency for drawing ions into the wafer W is applied thereto. The bias electrode 23 is a type of plasma generation electrode (RF electrode).

The gas passages 52 are passages through which gas can pass in the up-down direction of the ceramic plate 20. Here, the gas passages 52 are provided in an interior of a plug 50 fixed in a plug placement hole 24. The plug placement hole 24 is provided so as to penetrate the ceramic plate 20 in the up-down direction and communicate with a gas supply path 34 of the base plate 30. The plug placement hole 24 penetrates the electrostatic electrode 22 and the bias electrode 23 in the up-down direction, but the electrostatic electrode 22 and the bias electrode 23 are not exposed on an inner peripheral surface of the plug placement hole 24. The plug placement hole 24 is a tapered hole having an inverted frustoconical space in which an area of an upper opening is larger than an area of a lower opening. The plug placement holes 24 are provided at a plurality of positions (for example, a plurality of positions provided at equal intervals along a circumferential direction) of the ceramic plate 20 in a plan view. The plug 50 is a dense ceramic (for example, the same material as the ceramic plate 20) having an inverted frustoconical shape, disposed in the plug placement hole 24. The plug 50 is provided with gas passages 52 that penetrate from a lower surface to an upper surface of the plug 50 linearly in the up-down direction. An up-down-direction length L inside each gas passage 52 is the same as a thickness of the ceramic plate 20. A plurality of gas passages 52 (for example, six) are provided on an upper surface of the plug 50 along a circumferential direction in a plan view. A diameter (a length in a horizontal direction) of each gas passage 52 is set, preferably to 0.5 mm or less and more preferably to 0.2 mm or less, so as to suppress arc discharge. In the present embodiment, equipotential lines EL are oriented not in a horizontal direction but in the up-down direction or an oblique direction, as shown in FIG. 3. Arc discharge occurs when electrons generated in association with ionization of gas (for example, helium gas) in the gas passage 52 are accelerated in a direction of electric force lines (a direction orthogonal to the equipotential lines EL; in the present embodiment, a substantially horizontal direction) and collide with other helium; however, if the horizontal length, i.e., the diameter, of the gas passage 52 is 0.5 mm or less (preferably 0.2 mm or less), such arc discharge can be suppressed.

The base plate 30 is a conductive disk having good thermal conductivity (a disk having the same diameter as, or a larger diameter than, the ceramic plate 20). In the base plate 30, a refrigerant flow path 32 through which a refrigerant (for example, an electrically insulative liquid such as a fluorine-based inert liquid) circulates and the gas supply path 34 for supplying gas to the gas passages 52 are formed. The refrigerant flow path 32 is formed in a one-stroke pattern from an inlet to an outlet over an entire surface of the base plate 30 in a plan view. Examples of the material of the base plate 30 include metals and composite materials. Examples of the metals include Mo. Examples of the composite materials include composite materials of metal and ceramic. Examples of the composite materials of metal and ceramic include a metal matrix composite (MMC) and a ceramic matrix composite (CMC). Specific examples of such composite materials include a material containing Si, SiC, and Ti and a material obtained by impregnating a porous SiC body with Al and/or Si. A material containing Si, SiC, and Ti is referred to as SiSiCTi, a material obtained by impregnating a porous SiC body with Al is referred to as AlSiC, and a material obtained by impregnating a porous SiC body with Si is referred to as SiSiC. As the material of the base plate 30, it is preferable to select a material having a coefficient of thermal expansion close to that of the material of the ceramic plate 20. The base plate 30 is used as a source electrode (a type of plasma generation electrode (RF electrode)) to which a source high frequency for generating plasma is applied. For example, the bias high frequency is several hundreds of kHz, and the source high frequency is from several tens of MHz to several hundreds of MHz.

The gas supply path 34 includes, in a plan view, a ring portion 34b concentric with the base plate 30 and an introduction portion 34a for introducing gas from a lower surface of the base plate 30 into the ring portion 34b. The ring portion 34b communicates with the gas passages 52 via a through hole 42 of the metal bonding layer 40. The introduction portion 34a may be, for example, a single line. Gas introduced into the introduction portion 34a is distributed to the respective gas passages 52 through the ring portion 34b.

The metal bonding layer 40 bonds the lower surface of the ceramic plate 20 and an upper surface of the base plate 30. The metal bonding layer 40 is formed by, for example, TCB (Thermal Compression Bonding). TCB refers to a known method in which a metal bonding material is sandwiched between two members to be bonded, and the two members are pressure-bonded in a state heated to a temperature equal to or lower than a solidus temperature of the metal bonding material. The metal bonding layer 40 may be a layer formed of solder or a metal brazing material. The metal bonding layer 40 has the through hole 42. The through hole 42 is provided at a position where the gas passages 52 and the gas supply path 34 communicate with each other.

The electric-field-adjusting conductor 60 is a needle-like metal member provided in the interior of the plug 50 so as to extend in the up-down direction in the vicinity of the gas passages 52. The electrostatic electrode 22 has an electrostatic-electrode through hole 22a at a position facing the plug 50, and the bias electrode 23 has a bias-electrode through hole 23a at a position facing the plug 50. The electric-field-adjusting conductor 60 is embedded in the ceramic plate 20 in a state electrically insulated from the electrostatic electrode 22 and the bias electrode 23 inside the electrostatic-electrode through hole 22a and inside the bias-electrode through hole 23a. An upper portion of the electric-field-adjusting conductor 60 is inserted into a bottomed hole provided in a lower surface of the plug 50, and a lower portion of the electric-field-adjusting conductor 60 is in direct contact with the base plate 30. The lower portion of the electric-field-adjusting conductor 60 may be bonded to the base plate 30 by solder or a brazing material in a state inserted into a hole provided in the base plate 30, or may be screwed into the hole provided in the base plate 30. An upper end of the electric-field-adjusting conductor 60 reaches a position short of the wafer placement surface 21. The upper end of the electric-field-adjusting conductor 60 is positioned so as to maintain a withstand voltage between the electric-field-adjusting conductor 60 and the wafer W. As described above, the electric-field-adjusting conductor 60 is provided so as to extend in the up-down direction in the vicinity of the gas passages 52 from a position below the lower surface of the ceramic plate 20 to a position short of the wafer placement surface 21, and is electrically connected to the base plate 30. Therefore, the electric-field-adjusting conductor 60 is at the same potential as the base plate 30. For example, the electric-field-adjusting conductor 60 is provided at a position separated from the gas passages 52 by 0.3 to 2.0 mm.

Next, an example of use of the wafer placement table 10 configured as described above will be described. First, with the wafer placement table 10 installed in a chamber (not shown), the wafer W is placed on the wafer placement surface 21. Then, the chamber is depressurized by a vacuum pump and adjusted to a predetermined degree of vacuum, and a DC voltage is applied to the electrostatic electrode 22 of the ceramic plate 20 to generate an electrostatic attractive force, thereby attracting and fixing the wafer W to the wafer placement surface 21 (specifically, the upper surface of the seal band 21a and the upper surfaces of the circular small projections 21b). Next, the chamber is set to a reaction gas atmosphere at a predetermined pressure (for example, several tens to several hundreds of Pa), and in this state, a source high-frequency voltage is applied between an upper electrode (not shown) provided at a ceiling portion in the chamber and the base plate 30, and a bias high-frequency voltage is applied between the upper electrode and the bias electrode 23, thereby generating plasma. A surface of the wafer W is processed by the generated plasma. A refrigerant is circulated through the refrigerant flow path 32 of the base plate 30. Backside gas is introduced from a gas cylinder (not shown) into the gas supply path 34. As the backside gas, a heat transfer gas (for example, helium) is used. The backside gas is supplied and sealed in a space between a back surface of the wafer W and the reference surface 21c of the wafer placement surface 21 through the gas supply path 34, the through hole 42, and the gas passages 52. Due to the presence of the backside gas, thermal conduction between the wafer W and the ceramic plate 20 is efficiently performed.

In the wafer placement table 10, by providing the electric-field-adjusting conductor 60, a direction of an electric field at the time of plasma generation (a direction orthogonal to equipotential lines EL) can be adjusted to a horizontal direction or a direction close thereto. An example of the equipotential lines EL in the present embodiment is shown in FIG. 3. Accordingly, a direction in which electrons generated in association with ionization of gas molecules are accelerated becomes a horizontal direction or a direction close thereto. Therefore, if a length of the gas passages 52 in the horizontal direction or a direction close thereto is short, even when the up-down-direction length L in the gas passages 52 is increased, a distance over which electrons are accelerated does not become long, and discharge is less likely to occur even if accelerated electrons collide with other gas molecules. In contrast, when the electric-field-adjusting conductor 60 is not provided, horizontal equipotential lines EL exist over the entire up-down-direction extent of the gas passages 52 as in the comparative embodiment shown in FIG. 4. In that case, the direction of the electric field is the up-down direction. Therefore, when the up-down-direction length L in the gas passages 52 is increased, a distance over which electrons are accelerated also becomes long, and since the accelerated electrons have high energy, discharge is likely to occur due to collision with other gas molecules. Accordingly, when the electric-field-adjusting conductor 60 is not provided, instead of the gas passages 52 extending linearly in the up-down direction, for example, a spiral passage (having a short internal up-down-direction length (for example, 0.5 mm or less)) is employed to suppress discharge in the passage. According to the present embodiment, as compared with the case where the electric-field-adjusting conductor 60 is not provided, discharge in the gas passages 52 can be suppressed even when the up-down-direction length L in the gas passages 52 is increased.

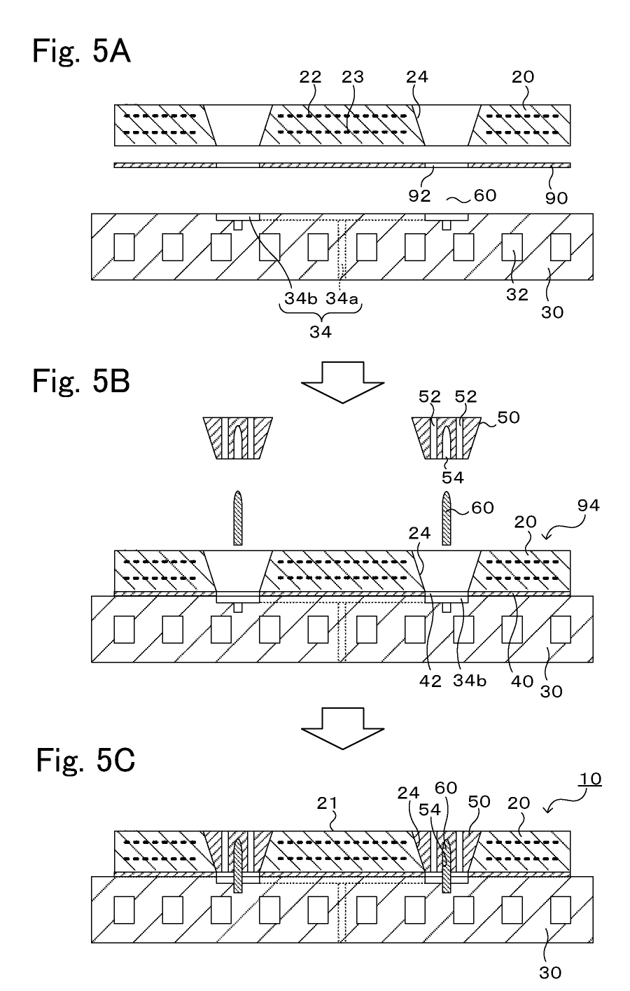

Next, a manufacturing example of the wafer placement table 10 will be described with reference to FIGS. 5A to 5C. FIGS. 5A to 5C are manufacturing process diagrams of the wafer placement table 10. First, the ceramic plate 20, the base plate 30, and a metal bonding material 90 are prepared (FIG. 5A). The ceramic plate 20 incorporates the electrostatic electrode 22 and the bias electrode 23, and includes the plug placement holes 24. The base plate 30 includes the refrigerant flow path 32 and the gas supply path 34. However, at this stage, an upper portion of the ring portion 34b is in an open state. Further, a hole for inserting the lower portion of the electric-field-adjusting conductor 60 is provided at a predetermined position of the ring portion 34b. The metal bonding material 90 includes a through hole 92 at a position facing the plug placement hole 24.

Subsequently, a laminate is formed by sandwiching the metal bonding material 90 between the lower surface of the ceramic plate 20 and the upper surface of the base plate 30. Then, the laminate is pressure-bonded at a temperature equal to or lower than the solidus temperature of the metal bonding material 90 (for example, a temperature equal to or higher than a temperature obtained by subtracting 20°C from the solidus temperature and equal to or lower than the solidus temperature), and thereafter returned to room temperature (TCB). As a result, the metal bonding material 90 and the through hole 92 become the metal bonding layer 40 and the through hole 42, respectively. Further, an upper portion of the ring portion 34b, except for a position facing the through hole 42, is covered with the metal bonding layer 40. As a result, a bonded body 94 is obtained in which the ceramic plate 20 and the base plate 30 are bonded by the metal bonding layer 40 (FIG. 5B). As the metal bonding material 90, an Al—Mg-based bonding material or an Al—Si—Mg-based bonding material can be used. The metal bonding material 90 preferably has a thickness of around 100 μm.

Subsequently, the electric-field-adjusting conductor 60 and a frustoconical plug 50 are prepared (FIG. 5B). The plug 50 has a plurality of gas passages 52 and has a bottomed hole 54 on a lower surface of the plug 50. The bottomed hole 54 is a hole for inserting an upper portion of the electric-field-adjusting conductor 60, and is provided at a center of a circle in which the plurality of gas passages 52 are arranged in a plan view. First, the electric-field-adjusting conductor 60 is inserted into the hole of the ring portion 34b and fixed by brazing or the like. Subsequently, the plug 50 is inserted into the plug placement hole 24 and fixed by an adhesive. At this time, the plug 50 is disposed such that the electric-field-adjusting conductor 60 is inserted into the bottomed hole 54 of the plug 50. Thereafter, an upper surface of the ceramic plate 20 is processed (to form the seal band 21a and the circular small projections 21b), whereby the wafer placement table 10 is obtained (FIG. 5C).

In the wafer placement table 10 described in detail above, by providing the electric-field-adjusting conductor 60, a direction of an electric field at the time of plasma generation (a direction orthogonal to equipotential lines EL) can be adjusted to a horizontal direction or a direction close thereto. Accordingly, a direction in which electrons generated in association with ionization of gas molecules are accelerated becomes a horizontal direction or a direction close thereto. Therefore, if a length of the gas passages 52 in the horizontal direction or a direction close thereto is short, even when the up-down-direction length L in the gas passages 52 is increased, a distance over which electrons are accelerated does not become long, and discharge is less likely to occur even if accelerated electrons collide with other gas molecules. Thus, as compared with the case where the electric-field-adjusting conductor 60 is not provided, discharge within the gas passages 52 can be suppressed even when the up-down-direction length L in the gas passages 52 is increased.

Further, the ceramic plate 20 has the electrostatic electrode 22 and the bias electrode 23. The gas passages 52 pass through the electrostatic-electrode through holes 22a such that the electrostatic electrode 22 is not exposed on the inner surfaces of the gas passages 52, and pass through the bias-electrode through holes 23a such that the bias electrode 23 is not exposed on the inner surfaces of the gas passages 52. The electric-field-adjusting conductor 60 is provided in a state electrically insulated from each of the electrostatic electrode 22 and the bias electrode 23. Therefore, a direction of an electric field generated by the electrostatic electrode 22 and the bias electrode 23 in the ceramic plate 20 can also be made a horizontal direction or a direction close thereto.

Further, the ceramic plate 20 has the plug placement holes 24 (ceramic-plate through holes) penetrating the ceramic plate 20 in the up-down direction. The gas passages 52 and the electric-field-adjusting conductor 60 are provided in the interior of the plug 50 disposed in the plug placement hole 24. Therefore, the gas passages 52 and the electric-field-adjusting conductor 60 may be more easily formed as compared with a case where the gas passages 52 and the electric-field-adjusting conductor 60 are provided directly in the ceramic plate 20 itself.

Further, the gas passages 52 are provided linearly in the up-down direction. As a result, gas flows more easily than in a case where a spiral passage is employed as the gas passage or fine pores inside a porous body are used as the gas passage, and thus a gas flow rate can be increased. Consequently, the number of gas passages 52 can be reduced. This reduces manufacturing cost. Further, the gas passages 52 become temperature singular points of the wafer W; by reducing the number thereof, the number of temperature singular points decreases, thereby improving temperature uniformity.

The present invention is not limited to the above-described embodiment, and various embodiments can be implemented as long as they fall within the technical scope of the present invention.

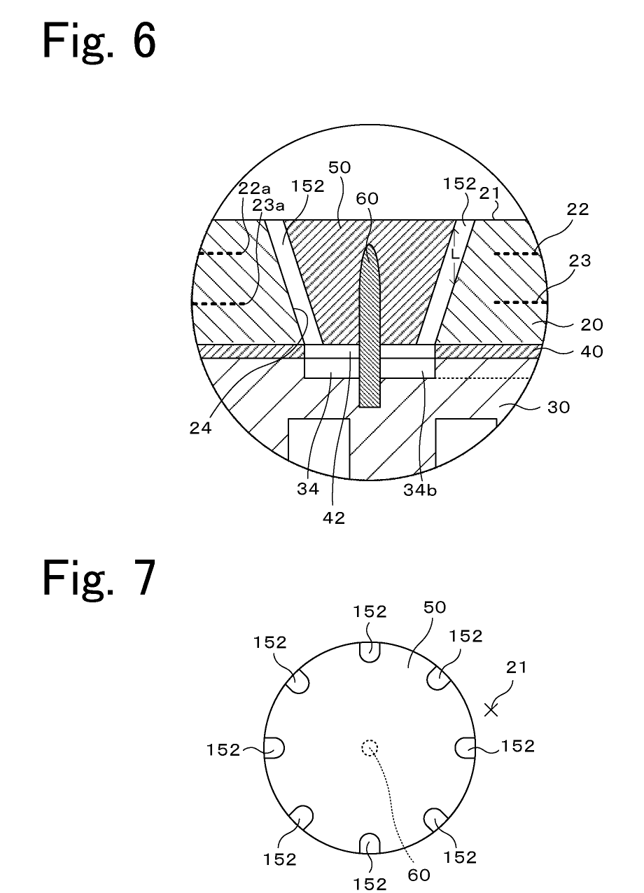

In the above-described embodiment, the gas passages 52 extending linearly in the up-down direction are provided in the interior of the plug 50; however, instead of the gas passages 52, gas passages 152 shown in FIG. 6 may be employed. In FIG. 6, the same reference numerals are assigned to the same components as those of the above-described embodiment. The gas passages 152 extend linearly in an oblique direction around the plug 50. Specifically, each gas passage 152 is formed by a groove provided in an outer peripheral surface of the plug 50 and an inner peripheral surface of the plug placement hole 24. As shown in FIG. 7, a plurality of gas passages 152 are provided at substantially equal intervals along an outer periphery of the plug 50 (a circle centered on the electric-field-adjusting conductor 60) in a plan view. The up-down-direction length L (FIG. 3) in the gas passages 52 is the same as the thickness of the ceramic plate 20, whereas an up-down-direction length L (FIG. 6) in the gas passages 152 is shorter than the thickness of the ceramic plate 20. Even with this configuration, the same effects as in the above-described embodiment can be obtained. The gas passages 152 may be provided in the interior of the plug 50 instead of around the plug 50. Alternatively, the gas passages 152 may be formed by an outer peripheral surface of the plug 50 and linear grooves provided in an inner peripheral surface of the plug placement hole 24.

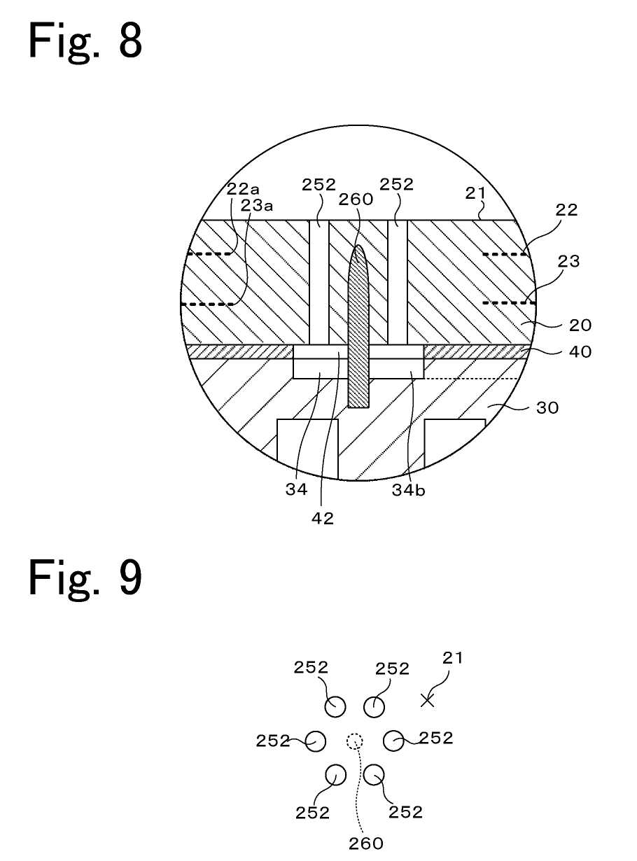

In the above-described embodiment, the gas passages 52 and the electric-field-adjusting conductor 60 are provided in the plug 50 disposed in the plug placement holes 24 of the ceramic plate 20; however, instead thereof, gas passages 252 and an electric-field-adjusting conductor 260 shown in FIG. 8 may be employed. In FIG. 8, the same reference numerals are assigned to the same components as those of the above-described embodiment. The gas passages 252 are provided in the ceramic plate 20 and extend linearly in the up-down direction. The gas passages 252 communicate with the gas supply path 34 and the through hole 42 and, as shown in FIG. 9, a plurality of gas passages 252 are provided at substantially equal intervals along a circle centered on the electric-field-adjusting conductor 260 in a plan view. An upper portion of the electric-field-adjusting conductor 260 is inserted into a bottomed hole provided on the lower surface of the ceramic plate 20, and a lower portion of the electric-field-adjusting conductor 260 is in direct contact with the base plate 30. Even with this configuration, the same effects as in the above-described embodiment can be obtained. Further, when manufacturing the ceramic plate 20, the gas passages 252 and the electric-field-adjusting conductor 260 (or a hole for inserting the electric-field-adjusting conductor 260) can be built into the ceramic plate 20. The gas passages 252 may be provided linearly in an oblique direction in the ceramic plate 20.

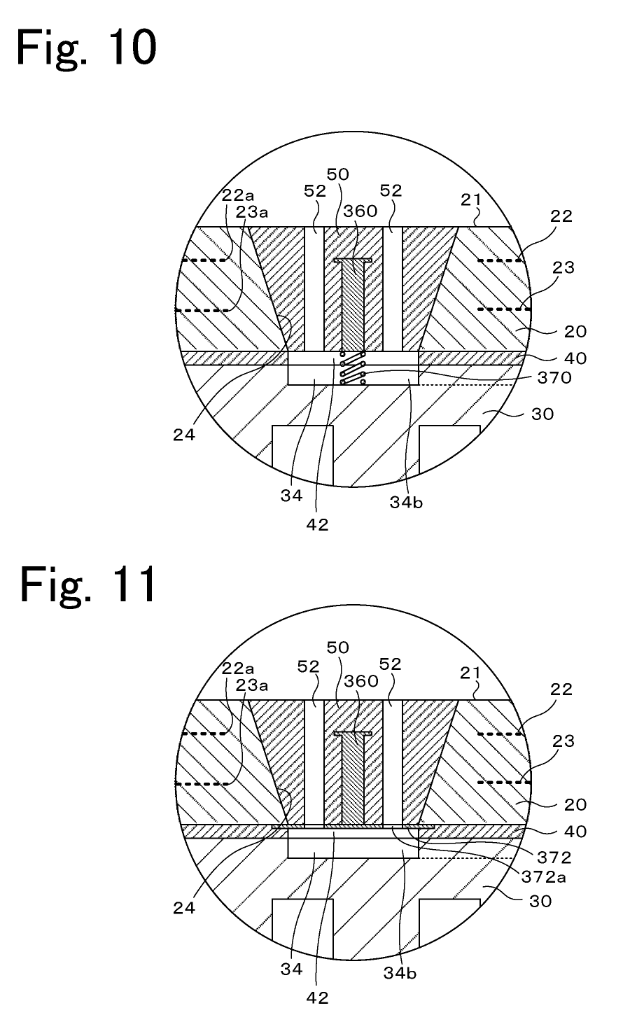

In the above-described embodiment, the electric-field-adjusting conductor 60 erected on the base plate 30 is inserted into the bottomed hole 54 of the plug 50; however, instead, the structure of FIG. 10 may be employed. In FIG. 10, the same reference numerals are assigned to the same components as those of the above-described embodiment. An electric-field-adjusting conductor 360 is a via provided in the plug 50. For example, a conductive paste as a precursor of the electric-field-adjusting conductor 360 may be embedded in a ceramic molded body that is a precursor of the plug 50, and the ceramic molded body may be fired to obtain the plug 50 such that the electric-field-adjusting conductor 360 is formed simultaneously. A metal spring 370 is disposed in a compressed state between a lower end of the electric-field-adjusting conductor 360 and a bottom surface of the gas supply path 34 (ring portion 34b) of the base plate 30. The electric-field-adjusting conductor 360 is electrically connected to the base plate 30 via the metal spring 370. The metal spring 370 maintains a communicating state between the gas supply path 34 and the gas passages 52. Even with this configuration, the same effects as in the above-described embodiment can be obtained. Although the metal spring 370 is exemplified in FIG. 10, the component is not limited to the metal spring 370 as long as it is a conductive elastic member that permits passage of gas in the up-down direction. For example, a metal mesh extendable/contractible in the up-down direction or a lump of metal fibers may be used. Such a structure is particularly useful when a resin adhesive layer is used instead of the metal bonding layer 40. The electric-field-adjusting conductor 360 and the metal spring 370 of FIG. 10 may be employed instead of the electric-field- adjusting conductors 60 and 260 of FIGS. 6 or 8 .

Further, instead of the metal spring 370 of FIG. 10, a conductive film 372 may be provided as shown in FIG. 11 so as to cover the lower surface of the plug 50 and cover a part of the lower surface of the ceramic plate 20 (around the plug placement hole 24). In FIG. 11, the same reference numerals are assigned to the same components as those of the above-described embodiment. The conductive film 372 is formed by, for example, sputtering or the like. A through hole 372a is provided at a position of the conductive film 372 facing the gas passages 52. Therefore, the conductive film 372 maintains the communicating state between the gas supply path 34 and the gas passages 52. The electric-field-adjusting conductor 360 is electrically connected to the base plate 30 via the conductive film 372 and the metal bonding layer 40. Even with this configuration, the same effects as in the above-described embodiment can be obtained. The electric-field-adjusting conductor 360 and the conductive film 372 of FIG. 11 may be employed instead of the electric-field-adjusting conductors 60 and 260 of FIGS. 6 or 8.

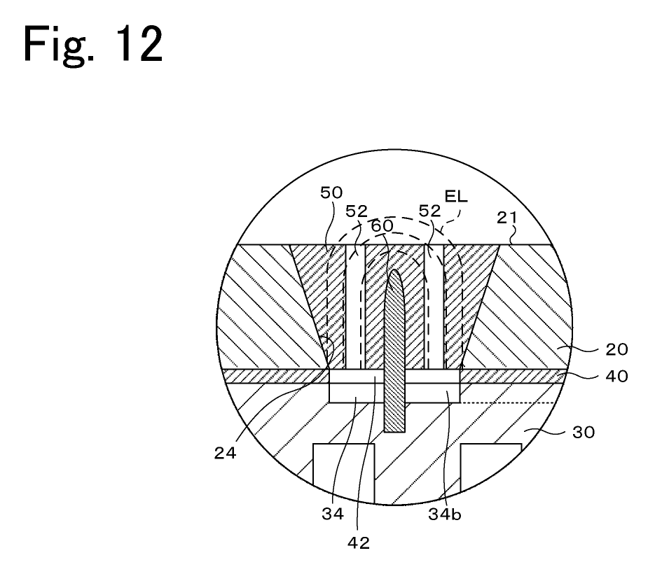

In the above-described embodiment, the electrostatic electrode 22 and the bias electrode 23 are embedded in the ceramic plate 20; however, at least one of the electrostatic electrode 22, the bias electrode 23, or a heater electrode capable of heating the wafer W may be embedded in the ceramic plate 20. Alternatively, these electrodes do not need to be embedded in the ceramic plate 20. FIG. 12 shows an example of a structure in which no electrode is embedded in the ceramic plate 20. In FIG. 12, the same reference numerals are assigned to the same components as those of the above-described embodiment. Equipotential lines EL are also shown in FIG. 12. In FIG. 12, by providing the electric-field-adjusting conductor 60, a direction of an electric field at the time of plasma generation (a direction orthogonal to the equipotential lines EL) can be adjusted to a direction close to horizontal. Accordingly, a direction in which electrons generated in association with ionization of gas molecules are accelerated becomes a direction close to horizontal. Therefore, as compared with a case where the electric-field-adjusting conductor 60 is not provided, discharge within the gas passages 52 can be suppressed even when the up-down-direction length in the gas passages 52 is increased.

In the above-described embodiment, a flexible conductive wire may be employed as the electric-field-adjusting conductor 60. This makes it possible to absorb positional deviation during manufacturing and deformation during use as compared with a case where a highly rigid needle-like member is employed as the electric-field-adjusting conductor 60. The same applies to the electric-field-adjusting conductor 260 of FIG. 8 and the electric-field-adjusting conductor 360 of FIGS. 10 and 11 .

In the above-described embodiment, the plug 50 is provided with a plurality of gas passages 52 extending linearly in the up-down direction; however, instead thereof, a single spiral passage may be employed, or a porous body may be employed as the plug 50 such that fine pores inside the porous body are used as gas passages. In these cases, discharge within the gas passage can be more easily suppressed; however, gas flows less easily than in the above-described embodiment.

In the above-described embodiment, the ceramic plate 20 and the base plate 30 are bonded by the metal bonding layer 40; however, a resin adhesive layer may be used instead of the metal bonding layer 40.

In the above-described embodiment, the gas supply path 34 having the introduction portion 34a and the ring portion 34b is exemplified; however, the gas supply path is not limited thereto. For example, a base-plate through hole penetrating the base plate 30 in the up-down direction and communicating with the gas passages 52 may be employed as a gas supply path.

In the above-described embodiment, an interior space of the plug placement hole 24 is an inverted frustoconical space; however, it may be a cylindrical space. In this case, the plug 50 is also formed in a cylindrical shape.

What is claimed is:

1. A wafer placement table comprising:
a ceramic plate having a wafer placement surface on its upper surface;
a gas passage through which gas can pass in an up-down direction of the ceramic plate;
a conductive base plate bonded to a lower surface of the ceramic plate and used as a plasma generation electrode;
a gas supply path provided inside the base plate and communicating with the gas passage; and
an electric-field-adjusting conductor provided so as to extend in an up-down direction in the vicinity of the gas passage from a position at a lower surface of the ceramic plate or a position below the lower surface to a position short of the wafer placement surface, the electric-field-adjusting conductor being electrically connected to the base plate.

2. The wafer placement table according to claim 1,
wherein the ceramic plate has at least one electrode,
the gas passage is provided so as to pass through an
electrode through hole provided for each of the at least one
electrode such that each of the at least one electrode is not exposed on an inner surface of the gas passage, and
the electric-field-adjusting conductor is provided in a state electrically insulated from each of the at least one electrode.

3. The wafer placement table according to claim 1,
wherein the ceramic plate has a ceramic-plate through
hole penetrating the ceramic plate in the up-down direction,
the gas passage is provided in an interior of a plug disposed in the ceramic-plate through hole or around the
plug, and
the electric-field-adjusting conductor is provided in
an interior of the plug.

4. The wafer placement table according to claim 1,
wherein the gas passage and the electric-field-adjusting conductor are embedded in the ceramic plate.

5. The wafer placement table according to claim 1,
wherein the gas passage is provided linearly in the up-down direction of the ceramic plate or in an oblique direction.

6. The wafer placement table according to claim 1,
wherein the electric-field-adjusting conductor is a flexible conductive wire.

7. The wafer placement table according to claim 1,
wherein a lower portion of the electric-field-adjusting conductor is provided so as to directly contact the base plate, or is electrically connected to the baseplate by a conductive elastic body that is disposed between the base plate and a lower end of the electric-field-adjusting conductor and that maintains a communicating state between the gas supply path and the gas passage, or is electrically connected to the base plate via a conductive film that is provided on a lower surface of the ceramic plate and that maintains the communicating state between the gas supply path and the gas passage.
